(19) United States
(12) Patent Application Publication
(10) Pub. No.: US 2002/0182758 A1
(43) Pub. Date: Dec. 5, 2002

(54) Circuit for compensation against back-gating

(76) Inventor: James G. Judkins, Campbell, CA (US)

Correspondence Address: TROPIAN, INC., ATTENTION: PATENT COUNSEL, Suite 150, 20813 Stevens Creek Boulevard, Cupertino, CA, 95014-5649, US

(21) Appl. No.: 09/874,458

(22) Filed: Jun. 4, 2001

(51) Int. Cl. H01L 21/00

(52) U.S. Cl. 438/10

(57) ABSTRACT

According to the invention, back-gating in a power FET caused by drain voltage changing rapidly from a higher voltage level to a lower voltage level is mitigated by use of a sensing FET that measures current flow whose level corresponds to the degree of back-gating. A compensation signal is generated using a voltage associated with the measure of current flow. A gate voltage is connected with a gate of the sensing FET and a gate of the power FET, wherein the gate voltage is adjusted or generated via a feedback path using the compensation signal such that the adjusted or generated gate voltage compensates against effects of back-gating. The sensing FET is located on a common substrate as the power FET.

### BACKGROUND OF THE INVENTION

This invention relates to FET circuits and more particularly to integrated power FETs. The invention is applicable in any case where power level must be pulsed or rapidly changed to different levels.

Certain semiconductor materials suffer from an undesirable charge trapping phenomenon known as back-gating, also known in the art as drain lag. For example, gallium arsenide (GaAs), due to its crystal lattice structure, exhibits back-gating as a characteristic that is manifested as deep traps of charges in the substrate embedded at a fast time constant but are released at a much slower time constant. When such charges are trapped, the behavior of the substrate, and thus the behavior of the device built using the substrate, deviates from expected characteristics. Specifically, in an FET device, characteristics such as the threshold voltage (V_{T}) and the drain current (I_{D}) versus drain voltage (V_{D}) curves are shifted from their normal values as a result of the trapped charges. Thus, any device operation that relies on a consistent V_{T} and a consistent set of I_{D} versus V_{D} curves is dramatically affected by the back-gating problem.

Back-gating is manifest in power amplifiers, particularly saturated power amplifiers, which are required to change power levels quickly. As the power level of such a power amplifier switches from a low value to a high value, deep traps of charges embed in the substrate at a fast constant. However, when the power level switches from a high value to a low value, the deep traps of charges are released at much slower time constant. The existence of the deep traps of charges alters the operating characteristics of the power amplifier. If the power amplifier is required to switch power levels quickly from a high level to a low level, such as switching on the order of microseconds, the deep traps of charges are not released quickly enough, since the charges can take on the order of minutes to be dissipated. Consequently, the output of the power amplifier is distorted as it attempts to perform power level changes.

Heretofore no effective solution has been found to prevent this phenomenon. Since many applications depend upon the ability of power amplifiers to change power levels at rates faster than the characteristically slow time constant for release of deep trap charges, there is a significant need for a circuit design that compensates against the detrimental effects of back-gating.

### SUMMARY OF THE INVENTION

According to the invention, back-gating in a power FET caused by drain voltage changing rapidly from a higher voltage level to a lower voltage level is mitigated by use of a sensing FET that measures current flow whose level corresponds to the degree of back-gating. A compensation signal is generated using a voltage associated with the measure of current flow. A gate voltage is connected with a gate of the sensing FET and a gate of the power FET, wherein the gate voltage is adjusted or generated via a feedback path using the compensation signal such that the adjusted or generated gate voltage compensates against effects of back-gating. The sensing FET is located on a common substrate as the power FET.

The measure of current flowing through said sensing FET corresponds to a shift in the threshold voltage of the sensing FET corresponding to effects of back-gating. Such current flow can be represented by a voltage across a resistor connected with said sensing FET.

In a specific embodiment, the compensation signal may be amplified using an inverting amplifier and a voltage reference circuit.

The invention will be better understood by reference to the following description in connection with the accompanying drawings.

### BRIEF DESCRIPTION OF THE DRAWINGS

FIG. 1A is a graph of the I_{D} versus V_{D} curves characterizing a power amplifier under normal conditions.

FIG. 1B is a graph of the I_{D} versus V_{D} curves under effects of back-gating for the power amplifier described in FIG. 1A.

FIG. 2 shows a circuit diagram of a power amplifier that may exhibit effects of back-gating.

FIG. 3A is a time-domain plot of a typical pulse input applied to the drain of the power amplifier of FIG. 2.

FIG. 3B is a time-domain plot of the desired power level output of the power amplifier of FIG. 2 under normal conditions, in response to the pulse input described in FIG. 3A.

FIG. 3C is a time-domain plot of the distorted power level output of the power amplifier of FIG. 2 under effects of back-gating, in response to the pulse input described in FIG. 3A.

FIG. 4 is a circuit diagram of an embodiment of the circuit according to the invention.

### DESCRIPTION OF SPECIFIC EMBODIMENTS

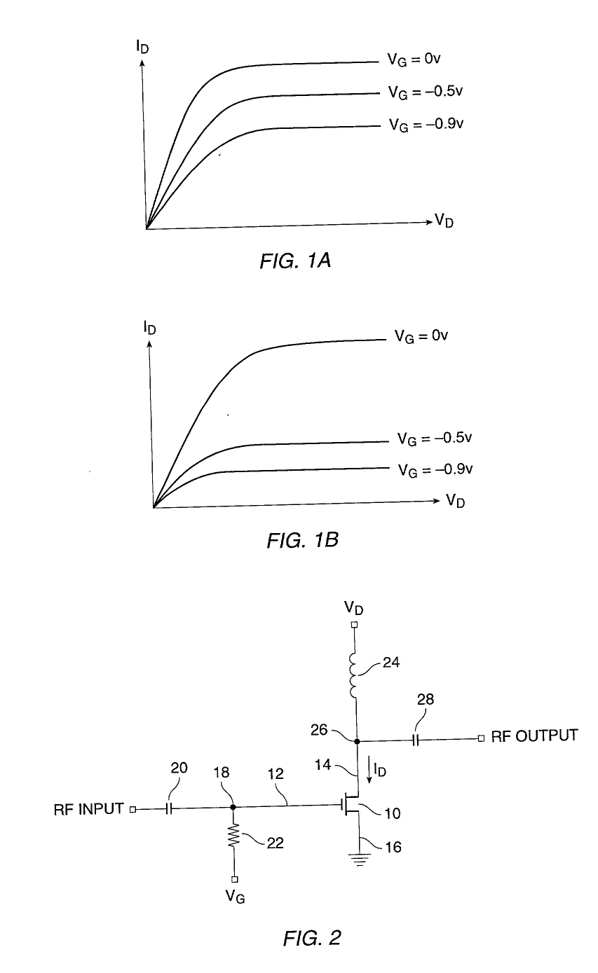

Referring to FIG. 1A, a graph is shown of the I_{D} versus V_{D} curves characterizing a power amplifier under normal conditions. FIG. 1B shows the same three I_{D} versus V_{D} curves for the power amplifier when it is under effects of back-gating. Note that the I_{D} versus V_{D} curves have shifted. The threshold voltage of the power amplifier also shifts due to back-gating. The result is that the back-gating causes the power amplifier to exhibit operating characteristics dramatically different from those it exhibits under normal conditions. Any operation that relies on consistent behavior of the power amplifier is severely impacted.

FIG. 2 shows a circuit diagram of a power amplifier that may exhibit effects of back-gating. As an illustrative example, power amplifier 10 is used to generate an amplitude modulation signal. Power amplifier 10 has a gate 12, a drain 14, and a source 16. Gate 12 is connected to a node 18, which is connected to a first end of capacitor 20 and a first end of resistor 22. An RF input is applied to a second end of capacitor 20. A gate voltage V_{G} is applied to a second end of resistor 22. A drain voltage V_{D}, which is used to quickly change the power levels of power amplifier 10, is applied to a first end of an inductor 24. A second end of inductor 24 is connected to a node 26. Node 26 is connected to drain 14. Node 26 is also connected to a first end of a capacitor 28. A second end of capacitor 28 is connected to an RF output. Source 16 is connected to ground.

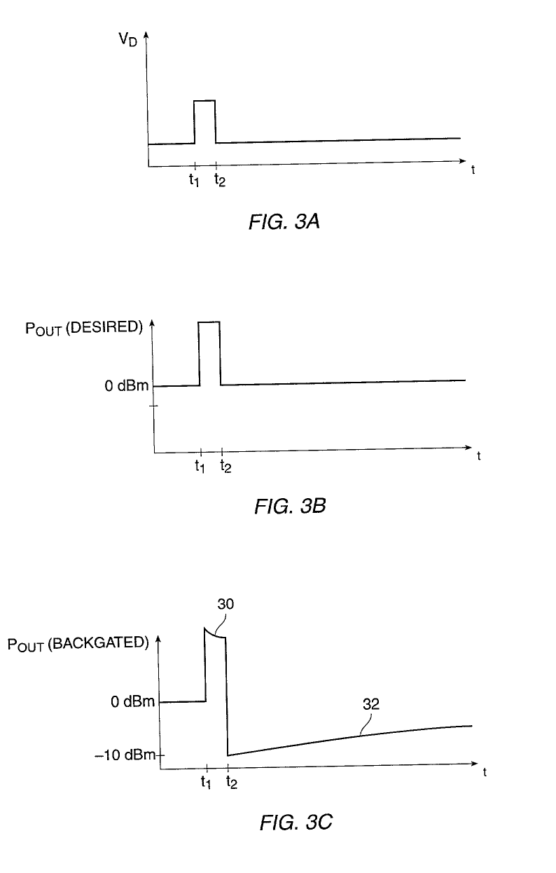

FIG. 3A is a time-domain representation of a typical pulse input V_{D} applied to drain 14 of the power amplifier 10. To generate an amplitude modulated signal, power amplifier 10 may be operated to increase it power level at time t₁, then decrease its power level at t₂. V_{D} provides the necessary control signal to operate power amplifier 10 in such a fashion.

FIG. 3B is a time-domain representation of the desired power level output of the power amplifier 10, in response to the pulse input described in FIG. 3A. Here, the power level of power amplifier 10 is initially operated at 0 dBm, then increased to a high level at t₁, then decreased back to 0 dBm at t₂.

FIG. 3C is a time-domain representation of the distorted power level output of the power amplifier 10 under effects of back-gating, in response to the pulse input described in FIG. 3A. Again, the power level of power amplifier 10 is initially operated at 0 dBm. When the power level is increased at t₁ to the high level, deep traps of charges embed in the substrate of power amplifier 10 at a fast time constant, and the power level settles to the high level rather quickly, as shown by portion 30 of the plot. However, when the power level is decreased at t₂, the deep traps of charges are released at much slower time constant. Consequently, the power level does not return to the desired level of 0 dBm, but instead decreases to −10 dBm. Only after a long delay corresponding to the much slower time constant, as shown by portion 32 of the plot, does the power level substantially return to the desired level of 0 dBm.

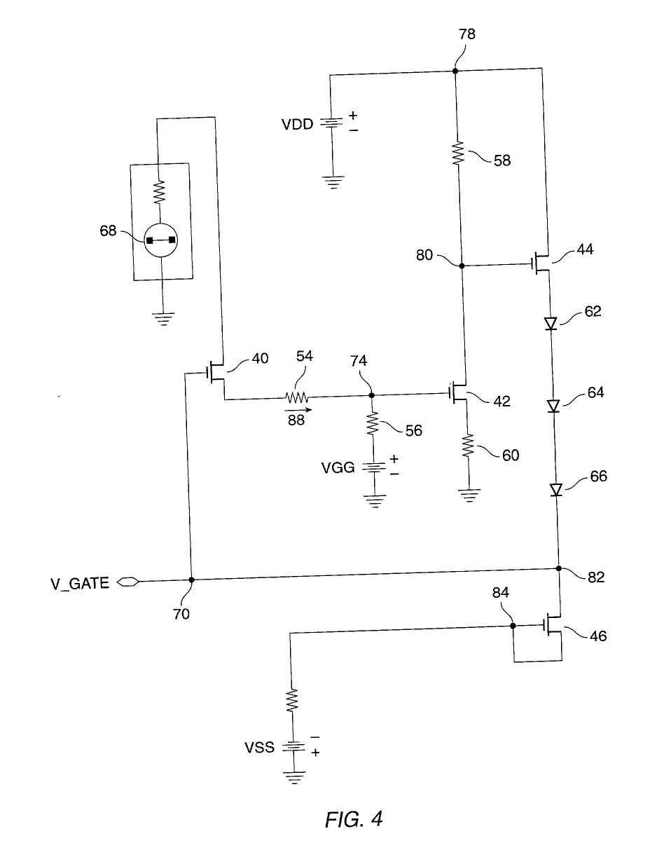

FIG. 4 is a circuit diagram of an embodiment of the circuit according to the invention. As an illustrative example, MESFETs are used for discussion of this embodiment. A sense transistor 40 is used for sensing the amount of back-gating effect occurring on a particular substrate. A pulsed input 68 that is applied to other MESFETs on the same substrate is applied to the drain of the sense transistor 40. A gate voltage V_GATE that is applied to other MESFETs on the same substrate is applied to the gate of the sense transistor 40. Thus, the sense transistor 40 experiences similar inputs and similar effects of back-gating as the other MESFETs on the same substrate.

As pulsed input 68 changes from an initial voltage to a higher level and back down to the initial voltage (a pulse), back-gating causes changes in the behavior of the substrate, including a shift in the threshold voltage V_{T} of the sense transistor 40 and other MESFETs on the substrate. By measuring the current of the sense transistor 40, the effects of back-gating can be estimated and thus compensated. The source of the sense transistor 40 is connect to a first end of a resistor 54. The other end of resistor 54 is connected to a node 74. Node 74 is connected to a first end of a resistor 56. The other end of resistor 56 is connected to a voltage reference VGG. A current 88 flows from the source of sense transistor 40 to node 74 through resistor 54. Current 88 generates a voltage at node 74. This voltage is a measure of current 88, which in turn, is a measure of the current of the sense transistor 40. This voltage is also substantially proportional to the shift in V_{T} caused by the back-gating effect.

The voltage at node 74 is amplified in order to provide the proper compensation to V_GATE. Node 74 is connected to the gate of an amplifier transistor 42. The source of the amplifier transistor 42 is connected to a first end of a resistor 60. The other end of resistor 60 is connected to ground. The drain of the amplifier transistor is connected to a node 80, which is connected to a first end of a resistor 58. The other end of resistor 58 is connected to a node 78, which is connected to a voltage source VDD. Node 80 is also connected the gate of a transistor 44. The drain of transistor 44 is connected to node 78. The source of transistor 44 is connected to serially-connected diodes 62, 64, and 66, which in turn are connected to node 82. The drain of a transistor 46 is connected to node 82. The source of transistor 46 is connected to its gate, which is connected to a voltage source VSS. This arrangement produces the compensation signal at node 82, which is connected to V_GATE.

Alternatively, the V_GATE signal can be used in the place of the voltage reference VGG to prevent the V_GATE signal from becoming positive and forward biasing MESFETs to which it is connected. As the V_GATE signal is pushed closer to zero Volts, the voltage difference between V_GATE and the voltage at node 74 decreases. This decrease reduces gain in the feedback, and V_GATE consequently approaches zero Volts asymptotically. Such protection against forward bias may not be important in certain MESFET configurations.

The above illustrative circuits provide feedback compensation to the V_GATE signal controlling the gates of MESFETs on the substrate such that effects of back-gating are significantly reduced. By using a sense transistor formed on the substrate where compensation is needed, the proper amount of feedback compensation is automatically provided, regardless of variations across different substrate in severity of back-gating effects. Furthermore, the compensation signal is quickly generated on the circuit level to rapidly control the gate bias voltage in order to track changes in drain voltage and control power output at appropriate power levels.

The invention has been explained with reference to specific embodiments. Other embodiments will be evident to those of ordinary skill in the art. It is therefore not intended that this invention be limited, except as indicated by the appended claims.

What is claimed is:

1. A method for correcting back-gating in a power FET caused by drain voltage changing rapidly from a higher voltage level to a lower voltage level comprising:
providing an input signal to a sensing FET located on a common substrate as said power FET, wherein said input signal is also provided to said power FET;
forming an output signal from said sensing FET, wherein said output signal is substantially proportional to a shift in threshold voltage of said sensing FET caused by effects of back-gating;
modifying said input signal using said output signal via a feedback path; and
providing said input signal to said power FET, wherein said input signal controls said power FET such that a shift in threshold voltage of said power FET caused by effects of back-gating are substantially reduced.

2. The method of claim 1, wherein the step of forming an output signal from said sensing FET further comprises a step for generating a voltage across a resistor connected to a source of said sensing FET, wherein said voltage across said resistor measures current flowing from said source of said sensing FET.

3. The method of claim 1, wherein the step of modifying said input signal using said output signal via a feedback path further comprises the steps of:
forming an error signal using said output signal;
amplifying said error signal to form an amplified error signal; and
adjusting or generating said input signal using said amplified error signal.

4. A method for correcting back-gating in a power FET caused by drain voltage changing rapidly from a higher voltage level to a lower voltage level comprising:
sensing said back-gating as a measure of current flowing through a sensing FET, wherein said sensing FET is located on a common substrate as said power FET, wherein a gate voltage is connected with a gate of said sensing FET and a gate of said power FET;
generating a compensation signal using a voltage associated with said measure of current flowing through said sensing FET; and
adjusting or generating said gate voltage via a feedback path using said compensation signal such that said adjusted or generated gate voltage compensates against effects of back-gating.

5. The method of claim 4, wherein said voltage associated with said measure of current flowing through said sensing FET is a voltage across a resistor connected with said sensing FET.

6. The method of claim 4, further comprising a step of amplifying said compensation signal before the step of adjusting or generating said gate voltage using said compensation signal.

7. The method of claim 6, where the step of amplifying said compensation signal is performed using a modified current mirror voltage reference source circuit.

8. The method of claim 4, further comprising a step of inverting said compensation signal before the step of adjusting or generating said gate voltage using said compensation signal.

9. The method of claim 8, where the step of inverting said compensation signal is performed using a modified current mirror voltage reference source circuit.

10. An apparatus for correcting back-gating in a power FET caused by drain voltage changing rapidly from a higher voltage level to a lower voltage level comprising:
a sensing FET sensing said back-gating as a measure of current flowing through said sensing FET, wherein said sensing FET is located on a common substrate as said power FET, wherein a gate voltage is connected with a gate of said sensing FET and a gate of said power FET;
a circuit generating a compensation signal by using a voltage associated with said measure of current flowing through said sensing FET; and
a feedback path using said compensation signal to adjust or generate said gate voltage such that said adjusted or generated gate voltage compensates against effects of back-gating.

11. The apparatus of claim 10, wherein said voltage associated with said measure of current flowing through said sensing FET is a voltage across a resistor connected with said sensing FET.

12. The apparatus of claim 10, further comprising an amplifier circuit for amplifying said compensation signal before using said compensation signal for adjusting or generating said gate voltage.

13. The apparatus of claim 12, wherein said amplifier circuit comprises a modified current mirror voltage reference source circuit.

14. The apparatus of claim 10, further comprising an inverting circuit for inverting said compensation signal before using said compensation signal for adjusting or generating said gate voltage.

15. The apparatus of claim 14, wherein said inverting circuit comprises a modified current mirror voltage reference source circuit.

16. A system for correcting back-gating in a power FET caused by drain voltage changing rapidly from a higher voltage level to a lower voltage level comprising:
means for sensing said back-gating as a measure of current flowing through a sensing FET, wherein said sensing FET is located on a common substrate as said power FET, wherein a gate voltage is connected with a gate of said sensing FET and a gate of said power FET;
means for generating a compensation signal using a voltage associated with said measure of current flowing through said sensing FET; and
means for adjusting or generating said gate voltage via a feedback path using said compensation signal such that said adjusted or generated gate voltage compensates against effects of back-gating.

17. The system of claim 16, wherein said voltage associated with said measure of current flowing through said sensing FET is a voltage across a resistor connected with said sensing FET.

18. The system of claim 16, further comprising means for amplifying said compensation signal before the step of adjusting or generating said gate voltage using said compensation signal.

19. The system of claim 18, where the means for amplifying said compensation signal further comprises a modified current mirror voltage reference source circuit.

20. The system of claim 16, further comprising means for inverting said compensation signal before the step of adjusting or generating said gate voltage using said compensation signal.

21. The system of claim 20, where the means for inverting said compensation signal further comprises a modified current mirror voltage reference source circuit.
